(19) United States
(12) Patent Application Publication
(10) Pub. No.: US 2009/0050199 A1
(43) Pub. Date: Feb. 26, 2009

(54) SEMICONDUCTING POLYMER FILMS WITH FIXED ELECTRONIC JUNCTIONS

(75) Inventors: Glenn P. Bartholomew, Seattle, WA (US); Janelle Leger, Seattle, WA (US); Deanna Rodovsky, Seattle, WA (US)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: WASHINGTON, UNIVERSITY OF, Seattle, WA (US)

(21) Appl. No.: 11/842,797

(22) Filed: Aug. 21, 2007

(51) Int. Cl. H01B 1/12; H01L 31/12

(52) U.S. Cl. 136/256; 252/500; 257/79; 257/E31.095

(57) ABSTRACT

A polymer film having fixed electronic junctions; devices that include the film; and methods for making and using the film.

### STATEMENT OF GOVERNMENT LICENSE RIGHTS

This invention was made with government support under Grant Numbers DMR-0120967 and CHE-0610193, awarded by the National Science Foundation. The government has certain rights in the invention.

### BACKGROUND OF THE INVENTION

Organic semiconductor materials and devices are beginning to infiltrate the electronics sector on a large scale, typically in short-term use devices that are quickly becoming a part of everyday life. It is estimated that organic electronic materials and devices will be a multibillion-dollar market in the next decade. Widespread interest in semiconducting polymers stems primarily from their exceptional processability. Polymers can be readily applied with solution techniques such as roll-to-roll coating, ink-jet printing, or even silk-screening. This unique advantage translates into low manufacturing costs and the potential for large area, conformal devices. An ideal system for polymer-based light-emitting devices would utilize simple solution techniques exclusively for the deposition of all layers.

One type of polymer light-emitting electrochemical cell (LEC) uses a self-assembled, dynamic p-i-n junction to overcome the sensitivity to top electrode quality that limits other electroluminescent devices, and may, therefore, be manufactured with a printed top contact, allowing the cell to be processed in an entirely roll-to-roll process and offering dramatically reduced production costs. For these reasons, the LEC has continued to be of interest, especially with regard to low-cost, short-term, or point-of-sale applications. Another important feature of the LEC is that its operation relies on a dynamic p-n or p-i-n junction within the bulk of the conjugated polymer film. The stabilization of such junctions formed in situ within a solution-processed semiconductor has great potential in the continuing expansion of organic materials in electronic and photonic devices.

Typical LECs use a salt, such as lithium trifluoromethanesulfonate (triflate), in a matrix of electroluminescent polymer, and an ion-conducting polymer. Under a suitable applied bias, the ions move to the electrodes and function as counterions in the reversible electrochemical doping of the electroluminescent polymer. The doped regions propagate from the electrodes until the applied potential drops over a relatively thin intrinsic region. All steps of device operation are reversible; once the bias that assembles the junction is removed, the device discharges and the ions redistribute. This results in long device charging times and over-doping of the light-emitting polymers, thereby significantly reducing operating efficiency and lifetimes. Methods for fixing the established charge distribution in an LEC have been attempted. These methods are either unstable at normal operating temperatures or are currently incompatible with existing emissive polymers.

### SUMMARY OF THE INVENTION

In one aspect, the present invention provides a method for making an electronic junction. In one embodiment, the method includes making a film from a solution that includes a solvent, a semiconducting polymer, a polymerizable anionic monomer, and a polymerizable cationic monomer; applying an electric field across the film for a time sufficient to produce a gradient distribution of polymerizable anionic and cationic monomers; and polymerizing the cationic and anionic monomers to provide an electronic junction in the film. The method provides an electronic junction formed in a semiconducting polymer through distribution of counterions fixed by covalent bonds.

In another aspect, the present invention provides a film that includes a semiconducting polymer, an anionic polymer, and a cationic polymer. The anionic polymer is made by polymerizing the anionic monomer. The cationic polymer is made by polymerizing the cationic monomer. In one embodiment, the film includes three regions: a first region that includes semiconducting polymer and an anionic polymer; a second region that includes the semiconducting polymer and a cationic polymer; and a third region, intermediate the first and second regions, that includes the semiconducting polymer.

In another aspect, the present invention provides an electroluminescent device. The electroluminescent device, also known as a light-emitting cell, includes a first electrode, a second electrode, and a polymer film intermediate the first and second electrodes. In one embodiment, the film has three regions: a first region that includes a semiconducting polymer and an anionic polymer; a second region that includes the semiconducting polymer and a cationic polymer; and a third region, intermediate the first and second regions, that includes the semiconducting polymer.

In another aspect, the present invention provides a photovoltaic device that includes a first electrode, a second electrode, and a polymer film intermediate the first and second electrodes. In one embodiment, the film has three regions: a first region that includes a semiconducting polymer and an anionic polymer; a second region that includes the semiconducting polymer and a cationic polymer; and a third region, intermediate the first and second regions, that includes the semiconducting polymer.

In another aspect, the present invention provides a method for producing light that includes applying a voltage in forward bias to the electrodes of an electroluminescent device. The device includes a first electrode, a second electrode, and a polymer film intermediate the first and second electrodes. In one embodiment, the film has three regions: a first region that includes a semiconducting polymer and an anionic polymer; a second region that includes the semiconducting polymer and a cationic polymer; and a third region, intermediate the first and second regions, that includes the semiconducting polymer.

In another aspect, the present invention provides a method for converting light into electricity that includes exposing a photovoltaic device to electromagnetic radiation. The device includes a first electrode, a second electrode, and a polymer film intermediate the first and second electrodes. In one embodiment, the first and second electrodes are in electrical contact with a device for receiving an electrical current from the photovoltaic device. The film includes three regions: a first region that includes a semiconducting polymer and an anionic polymer; a second region that includes the semiconducting polymer and a cationic polymer; and a third region, intermediate the first and second regions, that includes the semiconducting polymer.

### DESCRIPTION OF THE DRAWINGS

The foregoing aspects and many of the attendant advantages of this invention will become more readily appreciated as the same become better understood by reference to the following detailed description, when taken in conjunction with the accompanying drawings.

FIGS. 1A and 1B are schematic illustrations of methods for forming an electronic junction in a semiconducting polymer film; FIG. 1A illustrates mobile ions and FIG. 1B illustrates polymerizable ions.

FIGS. 2A-2D are illustrations of representative cationic and anionic polymerizable monomers, illustrated as ion-pairs, useful in the present invention; FIG. 2A illustrates MES/METMA, FIG. 2B illustrates AMPS/METMA, FIG. 2C illustrates AMPS/APTA, and FIG. 2D illustrates MES/VBDHA.

FIG. 3 is an illustration of a representative device of the present invention.

FIGS. 4A-4F are graphs illustrating current- and luminance-voltage measurements for light-emitting cells incorporating electronic junctions of the invention, formed using the semiconducting polymers MDMO-PPV (FIGS. 4A and 4B), PFO (FIGS. 4C and 4D), and DOF-MEH (FIGS. 4E and 4F). METMA/AMPS were used as the polymerizable ion-pair monomer for the MDMO-PPV and PFO devices, and METMA/MES were used in the DOF-MEH device.

FIGS. 4G-4I are the electroluminescence spectra produced from devices incorporating MDMO-PPV, PFO, and DOF-MEH, respectively.

FIG. 5 is a graph illustrating radiance as a function of current density for a representative MDMO-PPV-based electronic junction light-emitting cell of the invention using METMA/AMPS as the ion-pair monomer.

FIG. 6 is a graph comparing cyclic voltammograms for the oxidation of MDMO-PPV films using 0.01 M acetonitrile solutions of lithium triflate, METMA/AMPS, METMA/MES, and APTA/AMPS as electrolytes.

FIGS. 7A and 7B are graphs illustrating the current-voltage characteristics of a representative photovoltaic device having an MDMO-PPV semiconducting polymer fixed electronic junction formed using METMA/MES ion-pair monomers; FIG. 7A is the device under AM1.5 illumination and FIG. 7B is the device in the dark after charging for 0, 30, 90, and 180 minutes.

### DETAILED DESCRIPTION OF THE INVENTION

In one aspect, the present invention provides a method for making an electronic junction. In one embodiment, the method includes making a film from a solution that includes a solvent, a semiconducting polymer, a polymerizable anionic monomer, and a polymerizable cationic monomer; applying an electric field across the film for a time sufficient to produce a gradient distribution of polymerizable anionic and cationic monomers; and polymerizing the polymerizable cationic and anionic monomers to provide an electronic junction in the film.

As used herein, the term “polymer” refers to a chemical compound having more than one repeating unit (monomer unit) covalently coupled together. Polymers useful in the invention include compounds that are sometimes referred to in the art as oligomers. The method provides an electronic junction formed in a semiconducting polymer through distribution of counterions fixed by covalent bonds. As used herein, the term “electronic junction” refers to a semiconducting polymer film that has both p-type and n-type doping regions. These regions are typically formed by ionic species within the semiconducting polymer.

Because semiconducting polymers are distinguishable from traditional semiconductor materials, there is the potential for confusion when applying traditional semiconductor nomenclature to the present invention. The electronic junctions of the present invention can be classified as either homojunctions (same material, different doping) or heterojunctions (different doping via different materials) because the electronic junction film satisfies both definitions based on whether the ionic polymer is considered a “different material” or simply a dopant within the semiconducting polymer. The terms “heterojunction” and “homojunction” are used herein interchangeably with “electronic junction” and “junction.”

As used herein, the term “semiconducting polymer” refers to a polymeric material having a conductivity intermediate that of an insulator and a conductor. A semiconducting polymer can be a homopolymer or a blend of two or more semiconducting polymers. As used herein, the term “polymerizable anionic monomer” refers to a monomer containing a polymerizable group and an anionic group. As used herein, the term “polymerizable cationic monomer” refers to a monomer containing a polymerizable group and a cationic group.

The method for making an electronic junction includes making a film from a solution. A representative solution includes at least the semiconducting polymer, the polymerizable anionic monomer, and the polymerizable cationic monomer, dissolved in a solvent. Optionally, an ion-transport material, such as poly(ethylene oxide) (“PEO”) can be added to the solution. In a representative embodiment, the ratio of components of a solution useful in the invention is semiconducting polymer/poly(ethylene oxide)/ion-pair monomers at 10/4/1. A typical solution of the invention would include 10 mg of semiconducting polymer, 4 mg of poly(ethylene oxide), and 1 mg of ion-pair monomers in 1 g of solvent. The film is made from the solution by techniques known to those skilled in the art. Representative techniques include spin coating, roll coating, silk screening, and drop coating. The product of the film-making process is a solid film substantially free from solvent. After the solvent has evaporated, a solid film of semiconducting polymer, polymerizable anionic monomer, and polymerizable cationic monomer is formed. Heat, high-speed rotation (i.e., spin coating), an inert environment, and vacuum are methods known to assist in evaporating solvent. Representative films of the invention have a thickness from about 50 nm to about 1000 nm.

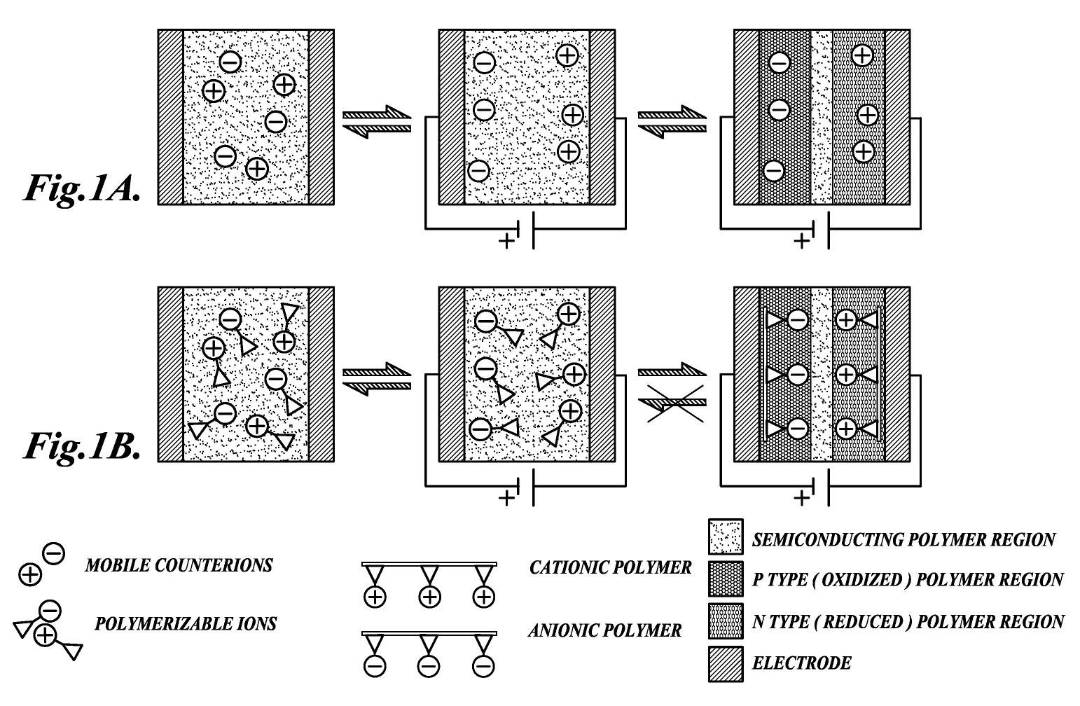

Once the film is solidified, an electric field is applied across the film for a time sufficient to produce a gradient distribution of the anionic and cationic monomers. For this polarization process there must be at least two electrodes: an anode and a cathode. With the film intermediate the anode and the cathode, a voltage is applied across the electrodes. As the electric field affects the film, the polymerizable anionic monomers and the polymerizable cationic monomers migrate within the film toward either the anode or the cathode, depending on the charge of the monomer ionic group. The product of the application of the electric field is a gradient distribution of the anionic and cationic monomers within the film. As used herein, the term “gradient distribution” means that the region near the anode is enriched with anions and the region near the cathode is enriched with cations. On a molecular level, a gradient distribution means that there are more anionic monomers than cationic monomers in the film area closest to the positive electrode and that there are more cationic monomers than anionic monomers in the film area closest to the negative electrode. This polarization leaves a central region, intermediate the two highly-concentrated areas of ionic monomers, with relatively fewer anionic and cationic monomers than are present near the anode and cathode. In this region, the semiconducting polymer is the predominant chemical species. The polarization process is illustrated in FIGS. 1A and 1B. The resulting film becomes a fixed p-i-n junction. The time that it takes to produce the gradient will depend on the size and chemical composition of the ionic monomers within the film, as well as the composition and size of film itself and the magnitude of the electric field applied.

Different end-use applications for the film may require different gradient distributions of the anionic and cationic monomers. For example, a light-emitting cell device incorporating the film made by the method of the present invention may be charged at 8 to 10 volts, using an indium tin oxide (ITO) anode and a gold cathode, until a steady-state current is achieved, typically 30 to 60 minutes. A steady-state current is a representative end point for the method of the present invention, and the gradient distribution of anionic and cationic monomers with a steady-state end point will depend on factors such as the size of the voltage applied, the distance the voltage is applied across, the composition of the film, the nature of the ionic monomers, and other factors. Once an appropriate end point is reached, whether it is based on the measurement of a steady-state current or other indicator, the end result of the polarization process is that a gradient distribution of anionic and cationic monomers is achieved.

In the final step of the method of the invention, the cationic and anionic monomers are polymerized. Polymerization is accomplished by any technique that will initiate the polymerization of the monomers. Representative polymerization techniques include radical, anionic, and cationic polymerization. Radical polymerization is representative and can be initiated by several different techniques, including charge-injection into the polymer at the electrodes, thermal treatment, the acceleration of polymerization through the addition of radical initiators (such as benzoyl peroxide), or through photo-excitation of a UV-visible-sensitive radical initiator (such as riboflavin). The degree of polymerization required is application-specific. However, a minimal degree of polymerization is required to provide the benefits of the invention by creating a fixed electronic junction within the film. Because all individual monomers in the film need not be polymerized, the final composition of the film may include unpolymerized monomers. The degree of polymerization will be affected by those factors known to those skilled in the art, including the length and/or amount of the polymerization-initiating event. Polymers useful in the invention will have at least two repeating units (monomer units joined covalently).

The final product of the method of the present invention is a fixed electronic junction film that includes a p-type region, an n-type region, and a region of intrinsic semiconductor material. The resulting film has a p-i-n junction within the film that is fixed or locked via the polymerization process and the ionic gradient distribution becomes permanent, as illustrated in FIG. 1B. Films with fixed electronic junctions are more efficient in applicable devices, such as LECs and photovoltaic cells. For example, in a traditional LEC, a salt is used to create an electronic junction, as illustrated in FIG. 1A. A voltage is first applied to mitigate the ions, until the desired charge distribution is reached, at which point electrons and holes, generated at the anode and cathode, respectively, combine in the semiconducting layer, and produce light. Traditional LECs have no mechanism for locking the ion distribution created by the electric field in place, making the devices susceptible to thermally-induced ion-pair movement (“relaxation”) of the charge distribution back to a more neutral film. In the present invention, the salt used in a traditional LEC is replaced with ion-pair monomers that can then be polymerized. Upon achieving a desired charge distribution, the monomers are immobilized in place and are not subject to further movement (“relaxation”). By the method of the invention, the post-polarization movement of ions that spoil the performance of traditional LECs is avoided. Additionally, unlike traditional LECs, the devices made using the method of the present invention yield junctions that are stable in both forward and reverse bias at room temperature, exhibit unipolar emission, and give rise to a significant photovoltaic effect.

In one embodiment, the method of the present invention uses a semiconducting polymer selected from poly[2-methoxy-5-(2′-ethyl-hexyloxy)-1,4-phenylene vinylene] (MEH-PPV, red emitter); poly[2-methoxy-5-(3′,7′-dimethyl-octyloxy)-p-phenylenevinylene] (MDMO-PPV, red emitter); poly(9,9-dioctylfluorenyl-2,7-diyl) (PFO, blue emitter); poly[2,5-di(2-ethylhexyloxy)-1,4-phenylenecyanovinylene] (BEH-CN-PPV); and poly[(9,9-dioctyl-2,7-divinylene-fluorenylene)-alt-co-{2-methoxy-5-(2-ethyl-hexyloxy)-1,4-phenylene}] (DOF-MEH, green emitter). Semiconducting polymers useful in the invention also include polyfluorenes and polyphenylenevinylenes. Molecular weights of semiconducting polymer useful in the invention have a broad range based on the individual compound and batch-to-batch variations in synthesis. A representative range of molecular weights useful in the invention is from about 150,000 g/mol to about 800,000 g/mol. Blends of more than one semiconducting polymers are also useful in the invention, as are blends of a semiconducting polymer and a non-polymeric molecule.

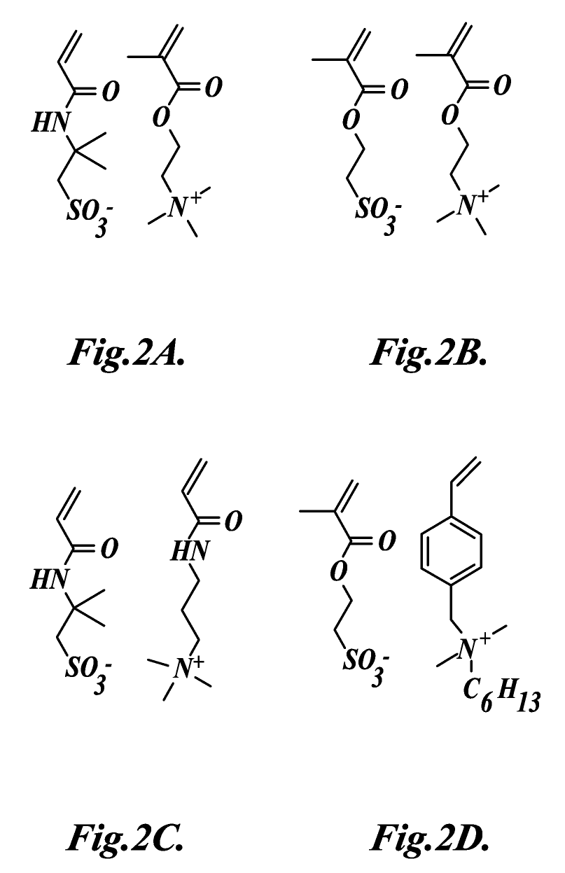

In one embodiment, the method of the present invention uses a polymerizable anionic monomer that is a thermoset monomer. The polymerizable anionic monomer and polymerizable cationic monomer useful in the method of the invention are non-polymerized molecules that contain both a charged group (e.g., trimethylammonium on a cationic monomer) and a polymerizable group (e.g., the radically polymerizable methylmethacrylate). One consideration for choosing polymerizable ionic monomers for the present invention is that the monomer polymerizes to form macromolecules that will have an overall positive or negative charge. The ionic monomers are integrated into the film of the invention through incorporation into the solution precursor to the film, either individually or combined as an ion-pair of monomers (IPMs). Examples of IPMs are illustrated in FIGS. 2A-2D. An example of an IPM is 2-acrylamido-2-methyl-1-propane sulfonate (AMPS)/[2-(methacryloyloxy)ethyl]trimethylammonium (METMA), illustrated in FIG. 2B. For IPMs, the concentration of the anionic and cationic monomers in the film solution will be approximately equal.

In one embodiment, the method uses a polymerizable anionic monomer that is selected from methylmethacrylate substituted with a negatively-charged group, methacrylate substituted with a negatively-charged group, acrylamide substituted with a negatively-charged group, and allyl substituted with a negatively-charged group. Mixtures of anionic monomers may also be used. In one embodiment, the negatively-charged group is sulfonate.

In one embodiment, the method uses a polymerizable anionic monomer selected from 2-acrylamido-2-methyl-1-propane sulfonate (AMPS), illustrated in FIGS. 2A and 2C, and 2-(methacryloyloxy)ethane sulfonate (MES), illustrated in FIGS. 2B and 2D.

In one embodiment, the method uses a polymerizable cationic monomer that is a thermoset monomer.

In one embodiment, the method uses a polymerizable cationic monomer that is selected from methylmethacrylate substituted with a positively-charged group, methacrylate substituted with a positively-charged group, acrylamide substituted with a positively-charged group, and allyl substituted with a positively-charged group. Mixtures of cationic monomers may also be used. In one embodiment, the positively-charged group is ammonium (e.g., trialkylammonium).

In one embodiment, the polymerizable cationic monomer is selected from [2-(methacryloyloxy)ethyl]trimethylammonium (METMA), illustrated in FIGS. 2A and 2B; (3-acrylamido-propyl)trimethylammonium (APTA), illustrated in FIG. 2C; and (4-vinylbenzyl)dimethylhexan-1-ammonium (VBDHA), illustrated in FIG. 2D.

In the method of the invention, the film is made by depositing a solution of polymerizable cationic monomer, polymerizable anionic monomer, and semiconducting polymer in a solvent. Suitable solvents dissolve the polymerizable cationic monomer, polymerizable anionic monomer, and the semiconducting polymer. In one embodiment, the solvent is selected from chlorobenzene, toluene, chloroform, tetrahydrofuran, cyclohexanone, methanol, and mixtures thereof.

In one embodiment, making the film includes making the film on a transparent conductive surface. The transparent conductive surface cannot be opaque, but need not be completely transparent. The transparent conductive surface need only allow some amount of light to pass. Transparency is necessary if the film is integrated into a light-emitting or photovoltaic device, both of which inherently require light to pass through one of the electrodes while traveling to or from the film. In a further embodiment, the transparent conductive surface is selected from indium-tin-oxide (ITO) and fluorine-doped tin-oxide. In a representative example of transparent conductive surfaces useful in the invention, an ITO layer of about 35 nm is deposited on a glass substrate.

In one embodiment, making the film includes forming a metallic electrode on the film surface. Representative metallic electrodes include electrodes made from gold, silver, aluminum, copper, barium, calcium, and mixtures thereof. Typical metal films useful in the invention are from about 10 to about 100 nm thick.

Either electrode can also be made of an organic conductor. Organic conductors include polymer conductors. Organic conductors can be solution-coated or vapor-deposited onto the film.

In one embodiment, making the film includes making the film on a transparent conducive surface and forming a metallic electrode on the film surface opposite the transparent conductive surface. The film can also be made on a metallic electrode with a transparent conductive surface deposited on the film surface opposite the metallic conductor. For light-emitting or photovoltaic applications, a representative metallic electrode will be reflective, so as to preferentially direct the light to (or from) the film, through the transparent conductor. Both the transparent conductive surface and the metallic electrode can be formed using a sputtering or evaporative process.

A representative structure produced by the method of the present invention is a layered structure with a glass or plastic substrate supporting a transparent conductor, such as indium-tin-oxide. The film that includes the semiconducting polymer and ionic monomers is made on the transparent conductor, on top of which the metallic electrode is formed. The result is a layered structure that includes a substrate, a first (lower) electrode, the electronic junction film of the invention, and a second (upper) electrode. Devices having this structure operate by applying a voltage to the first and second electrodes to generate light in the semiconducting polymer (e.g., LEC). In an alternative operation mode, the structure functions as a photovoltaic device that uses the film of the invention to convert electromagnetic radiation into electricity.

The mobility of the ionic monomers in the film can be enhanced by adding an ion-transport component to the initial solution that includes the semiconducting polymer, the polymerizable anionic monomer, and the polymerizable cationic monomer. In one embodiment, the solution further includes an ion-transport material. In one embodiment, the amount of ion-transport material included in the initial solution will be dependent on the amount of semiconducting polymer, and will typically be a lesser weight amount than that of the semiconducting polymer. A representative initial solution includes semiconducting polymer:ion-transport polymer:ion-pair monomer in an 8:2:1 ratio (by weight) mixed in solution. Representative ion-transport materials include ion-transport polymers or neutral thermoset monomers similar in structure to either the polymerizable anionic or polymerizable cationic monomer. The addition of ion-transport materials facilitates the anionic and cationic monomer movement within the film when the electric voltage is applied to the anode and cathode, and before the monomers are polymerized. As a result of enhanced ion-transport, the gradient distribution of the ionic monomers will be more greatly concentrated at the respective electrodes.

In one embodiment, the ion-transport polymer includes poly(ethylene oxide). In a representative example, the poly(ethylene oxide) has a molecular weight of from about 100,000 g/mol to about 5,000,000 g/mol.

In one embodiment, the ion-transport material includes a neutral thermoset monomer. The neutral thermoset monomer is a monomer similar in structure to either the polymerizable anionic or polymerizable cationic monomers. In a representative embodiment, the neutral thermoset monomer is the non-ionically-substituted core of a polymerizable ionic monomer. In a representative example, if the polymerizable anionic monomer were a methacrylate substituted with an anionic group, the corresponding ion-transport monomer would be the methacrylate without the anionic substituent.

In one embodiment, the neutral thermoset monomer is selected from a polymerizable crown ether, methacrylate, methylmethacrylate, and styrene. When a neutral thermoset monomer is used for ion-transport, it is not essential that the neutral thermoset be of the same base-structure as the ionic monomers.

In another aspect, the present invention provides a film that includes a semiconducting polymer, an anionic polymer, and a cationic polymer. The anionic polymer is made by polymerizing the anionic monomer. The cationic polymer is made by polymerizing the cationic monomer.

In one embodiment, the film includes three regions: a first region that includes the semiconducting polymer and an anionic polymer; a second region that includes the semiconducting polymer and a cationic polymer; and a third region, intermediate the first and second regions, that includes the semiconducting polymer. In this embodiment, the invention provides a gradient distribution of ionic polymers across the film (i.e., from the first region to the second region through the third region). The semiconducting polymer is the common element in all three regions and can be considered a host to the anionic and cationic polymers. In the first region there are more anionic polymers than cationic polymers (i.e., there are more anionic groups than cationic groups, giving the region a net anionic charge). In the second region there are more cationic polymers than anionic polymers. In the third region there may be a small concentration of cationic and anionic polymer (i.e., fewer anionic polymers than in the first region and fewer cationic polymers than in the second region), or no ionic polymers at all. The ionic polymers are concentrated in either the first or the second region based on their polarity. In the film of the invention, there may be anionic polymers in the second region and/or cationic polymers in the first region. However, these will be fewer in number than the oppositely-charged species.

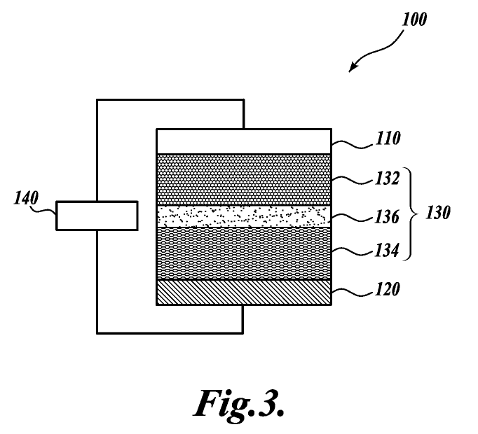

A representative device of the present invention is illustrated in FIG. 3. The device can be used for both electroluminescent and photovoltaic functions. Referring to FIG. 3, device 100 includes first electrode 110, second electrode 120, and polymer film 130 intermediate the first and second electrodes. Polymer film 130 has three regions: first region 132 that includes a semiconducting polymer and anionic polymer; second region 134 that includes semiconducting polymer and cationic polymer; and third region 136, intermediate the first and second regions, that includes semiconducting polymer. The operation of the device as either an electroluminescent or photovoltaic device is determined by electrical unit 140 that is in electrical contact with first electrode 110 and second electrode 120. If electrical unit 140 is an electrical source (e.g., wall power) then the device of the invention will operate as an electroluminescent device and emit light. If the electrical unit 140 is a device in need of electricity (e.g., a depleted rechargeable battery) then the device of the invention will operate as a photovoltaic device and will convert electromagnetic radiation into electricity. The electricity can then be used by the electrical unit device in need of electricity (e.g., to recharge the depleted rechargeable battery).

In another aspect, the present invention provides an electroluminescent device. This embodiment includes the electroluminescent device know as a light-emitting cell. The electroluminescent device includes a first electrode, a second electrode, and a polymer film intermediate the first and second electrodes. In one embodiment, the film has three regions: a first region that includes a semiconducting polymer and an anionic polymer; a second region that includes the semiconducting polymer and a cationic polymer; and a third region, intermediate the first and second regions, that includes the semiconducting polymer. A representative electroluminescent device of the present invention is illustrated in FIG. 3. The electroluminescent device of the invention is operated by applying a voltage in forward electrical bias across the first and second electrodes. If the first electrode is wired as the anode (positive contact) then the anionic polymer will be concentrated in the region of the film nearest to the anode, and as the bias is applied, the semiconducting polymer near the anode will become oxidized and will become a p-type material. On the opposite side of the film, at the cathode, the polymer film region near the cathode will have a concentration of cationic polymer; as the bias is applied, the semiconducting polymer will be reduced, thus creating an n-type material. If the bias is continually applied across the device, the n-type and p-type regions will expand toward each other. Once the n-type and p-type regions expand so that they are in close proximity, the n-type and p-type carriers recombine in the intermediate (primarily) semiconducting region. The combination of charge carriers produces molecular excitation in the semiconductor that results in the emission of light via electroluminescence. For the light produced by the LEC to escape the device, in one embodiment, the first or second electrode is a transparent conductor. Example 1 describes the fabrication and testing of a representative LEC of the present invention.

In another aspect, the present invention provides a photovoltaic device that includes a first electrode, a second electrode, and a polymer film intermediate the first and second electrodes. In one embodiment, the film has three regions: a first region that includes a semiconducting polymer and an anionic polymer; a second region that includes the semiconducting polymer and a cationic polymer; and a third region, intermediate the first and second regions, that includes the semiconducting polymer. A representative photovoltaic device of the present invention is illustrated in FIG. 3. The photovoltaic device of the present invention uses the photovoltaic properties of the semiconducting polymer and the hole- and electron-transporting properties of the p-type and n-type semiconducting polymer regions to convert electromagnetic radiation into electricity. By putting a device for receiving an electrical current in electrical contact with the first and second electrodes of the photovoltaic device of the invention, the electricity generated by the photovoltaic device can be utilized. For operation as a photovoltaic device, electromagnetic radiation must be allowed to contact the semiconducting polymer, thus, in one embodiment, the first or second electrode is a transparent conductor. Example 2 describes the operation and testing of a representative photovoltaic device of the present invention.

In another aspect, the present invention provides a method for producing light that includes applying a voltage in forward bias to the electrodes of an electroluminescent device. In one embodiment, the device includes a first electrode, a second electrode, and a polymer film intermediate the first and second electrodes. In one embodiment, the film has three regions: a first region that includes a semiconducting polymer and an anionic polymer; a second region that includes the semiconducting polymer and a cationic polymer; and a third region, intermediate the first and second regions, that includes the semiconducting polymer.

In another aspect, the present invention provides a method for converting light into electricity that includes exposing a photovoltaic device to electromagnetic radiation. In one embodiment, the device has a first electrode, a second electrode, and a polymer film intermediate the first and second electrodes. In one embodiment, the first and second electrodes are in electrical contact with a device for receiving an electrical current from the photovoltaic device. The film includes three regions: a first region that includes a semiconducting polymer and an anionic polymer; a second region that includes the semiconducting polymer and a cationic polymer; and a third region, intermediate the first and second regions, that includes the semiconducting polymer.

The following examples are provided for the purpose of illustrating, not limiting, the invention.

### EXAMPLES

### Example 1

### Fabrication and Testing of Representative LEC Devices of the Invention Integrating Semiconducting Polymers With Fixed Electronic Junctions

The materials used include lithium triflate, poly(ethylene oxide) (PEO), emissive polymers, and ion-pair monomers (IPMs). Lithium triflate and PEO were obtained from Sigma Aldrich and used without further purification. Light-emitting polymers MEH-PPV, PFO, and DOF-MEH were obtained from American Dye Source. MDMO-PPV was synthesized using a Gilch polymerization route via dehydrohalogenation of appropriate precursors. The IPMs used were synthesized using commercially available starting materials paired by means of a salt metathesis that eliminates the non-polymerizable counterions through a precipitation reaction resulting in silver chloride. All pairs were characterized using ¹H NMR and subjected to testing with excess silver nitrate and sodium chloride to detect unpaired monomers.

Devices were constructed in a single-layer architecture by spin-casting polymer solution to a thickness of 200-500 nm onto patterned ITO/glass substrates. The solution composition was light-emitting polymer, PEO, and IPMs in a 10:4:1 ratio at approximately 1% (total weight) in chlorobenzene. The polymer films were annealed on a hot plate in inert atmosphere at 80° C. for one hour. Gold top electrodes were deposited by thermal evaporation at 10⁻⁷ torr following overnight drying under vacuum. Devices were charged at 8-10 V (with ITO biased as the anode) at room temperature until a steady current was achieved, approximately 30-60 minutes. After charging, the voltage was swept in 0.2 V increments with a 1500 ms delay between step and measure. All device testing took place in a dry nitrogen glove box using a Keithley 2400 Sourcemeter. Electroluminescence measurements were taken using a calibrated Ocean Optics USB2000 fiber optic spectrometer. Film thickness was measured on a Dimension 3100 Atomic Force Microscope.

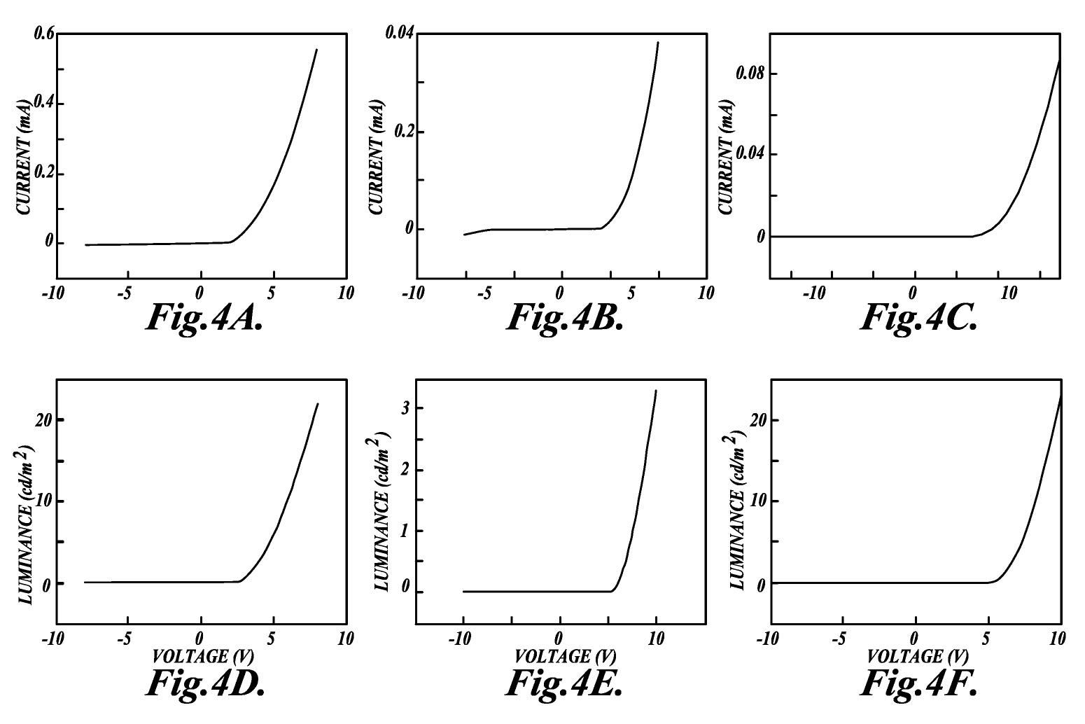

The current-voltage and luminance-voltage curves for MDMO-PPV, PFO, and DOF-MEH ion-pair monomer fixed-junction LEC are illustrated in FIGS. 4A-4F. All three polymer devices show excellent rectification (rectification ratios greater than 100 are commonly observed at high operating voltages) and unipolar current and emission characteristics, indicating the formation of a fixed electronic junction in the film. The fabricated pixels were separately charged and tested less than 1 mm apart on the same substrate without noticeable decrease in performance from pixel to pixel.

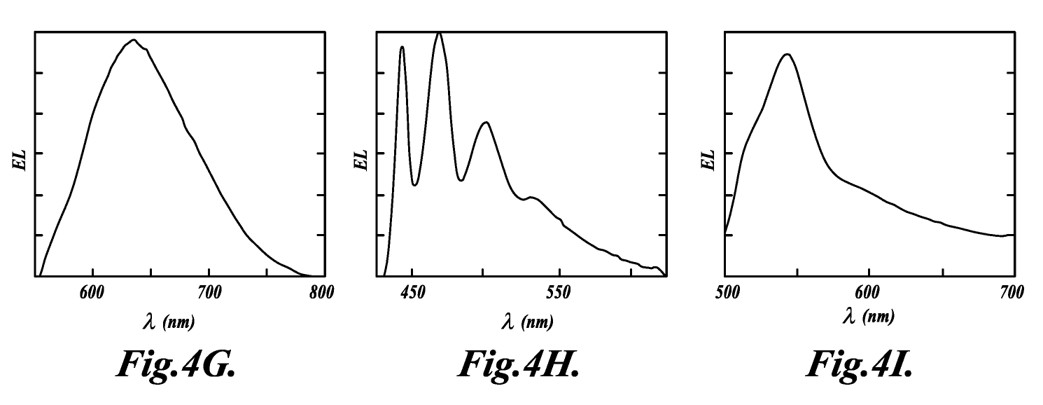

A distinguishing characteristic of a fixed electronic junction is the linearity of radiance versus current. In a dynamic LEC, as the current increases, the radiance falls off in a sublinear fashion throughout its range of current densities. For a fixed junction, this relationship is linear until the device breaks down. FIG. 5 illustrates radiance values for a representative fixed junction LEC of the present invention (incorporating MDMO-PPV as the semiconducting polymer) under a range of current densities for a 340 nm thick film. The linear response conforms to expectations for a fixed-junction device.

Electrochemistry experiments were performed using a non-aqueous silver/silver-ion reference electrode (Ag/Ag⁺, 0.3 V vs. SCE), a platinum counter electrode, and a polymer film on ITO as a working electrode. Polymer films were spin-cast from solution in chlorobenzene to achieve a film thickness of approximately 50 nm for all materials. Following polymer deposition, the substrates were dried in a vacuum chamber overnight. The electrolyte consisted of 0.01 M lithium triflate or IPMs in acetonitrile, and was purged with nitrogen for 5 minutes prior to testing to reduce air contamination. Electrochemical data was obtained on an Eco Chemie Autolab potentiostat.

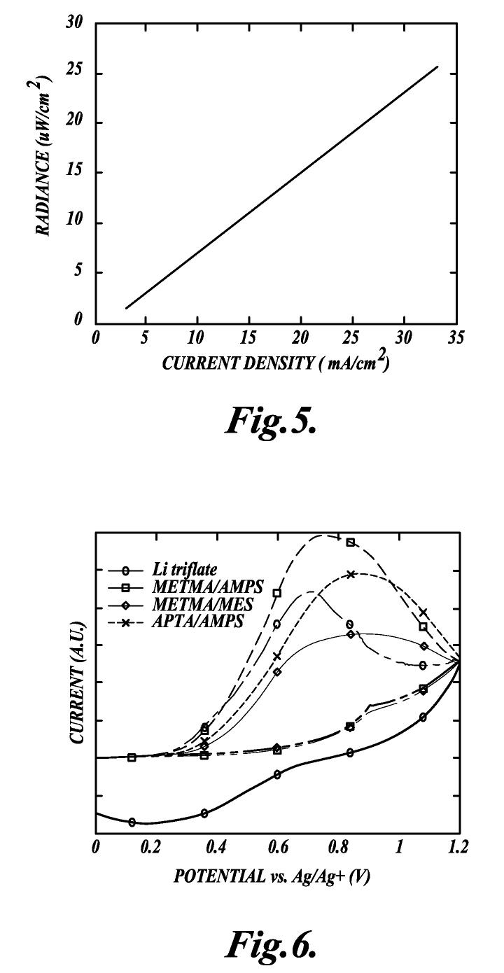

Electrochemical studies were performed on polymer films using ion-pair monomers as counterions to probe the mechanism by which ions are fixed in the polymer film. Cyclic voltammetry experiments were carried out using MDMO-PPV films on ITO, with the results graphically illustrated in FIG. 6. Electrochemical studies of METMA/AMPS alone indicate that no oxidation, reduction, or electrochemical polymerization of the material occurs within the electrochemical window of the polymer. Oxidizing the polymer film using the ion-pair monomers as counterions results in an irreversible reaction, a slightly lower doping onset, and a lack of the typically observed high-voltage over-oxidation peak when compared to oxidation using lithium triflate.

### Example 2

### Representative Photovoltaic Devices of the Invention Integrating Semiconducting Polymers with Fixed Electronic Junctions

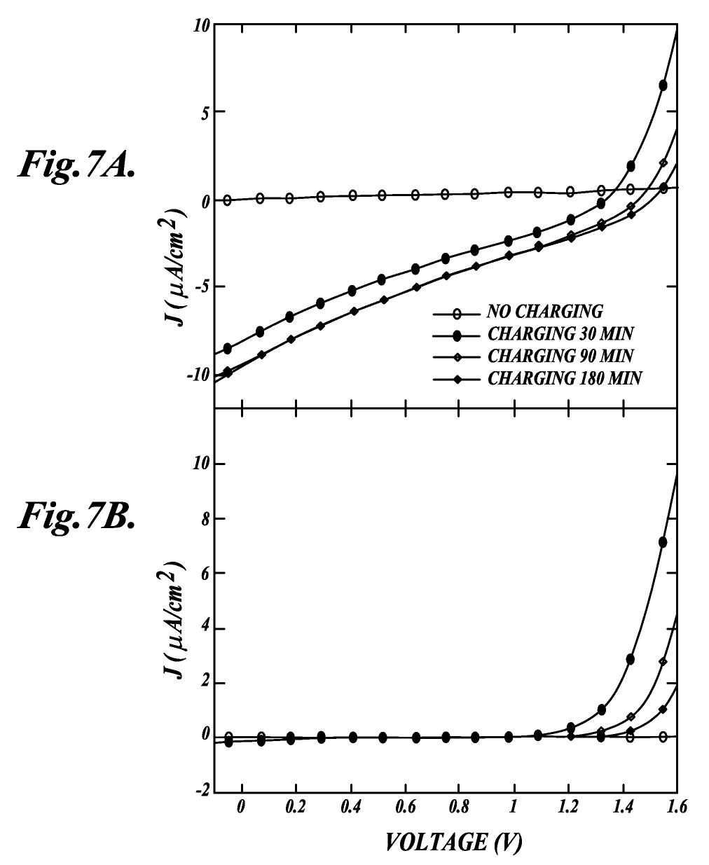

One significant advantage of the methods, compositions, and devices of the present invention, in comparison to a standard LEC, is the stability of the junction with no applied bias. This stability allows the invention to be utilized in, photovoltaic and multiple-junction applications. Both a charged and an uncharged single-layer device for photovoltaic response were constructed and charged using the same materials and procedures as the light-emitting devices of Example 1. A representative photovoltaic device of the present invention is illustrated in FIG. 3. The device was fabricated using an METMA/MES ion-pair monomer in MDMO-PPV semiconducting polymer. The complete composition of the film was MDMO-PPV:PEO:METMA/MES in an 8:2:1 ratio. Photovoltaic measurements were taken at 100 mW/cm², with AM1.5 white light, using an ORIEL Solar Simulator and monochrometer. The film of the invention is 500-600 nm thick. Prior to charging, ion separation, and polymerization, the devices performed as expected for a single layer device, with an open circuit voltage (V_{OC}) of 37 mV and a short circuit current (I_{SC}) of 8 nA/cm². After charging, ion separation, and polymerization, the devices systematically showed an enhanced photovoltaic performance, with V_{OC} increasing to 1.5 V and I_{SC} increasing to 10 PA/cm². The current-voltage characteristics of a representative photovoltaic device of the invention are graphically illustrated in FIGS. 7A and 7B. The fill factor of the fixed junction device is approximately 24-30%. In addition, the spectral response observed correlates well with the absorption spectrum of the polymer.

The embodiments of the invention in which an exclusive property or privilege is claimed are defined as follows:

1. A method for making an electronic junction, comprising:
(a) making a film from a solution comprising a solvent, a semiconducting polymer, a polymerizable anionic monomer, and a polymerizable cationic monomer;
(b) applying an electric field across the film for a time sufficient to produce a gradient distribution of polymerizable anionic and cationic monomers; and
(c) polymerizing the polymerizable cationic and anionic monomers to provide an electronic junction in the film.

2. The method of claim 1, wherein the semiconducting polymer is selected from the group consisting of poly[2-methoxy-5-(2′-ethyl-hexyloxy)-1,4-phenylene vinylene]; poly[2-methoxy-5-(3′,7′-dimethyl-octyloxy)-p-phenylenevinylene]; poly(9,9-dioctylfluorenyl-2,7-diyl); and poly[(9,9-dioctyl-2,7-divinylene-fluorenylene)-alt-co-{2-methoxy-5-(2-ethyl-hexyloxy)-1,4-phenylene}].

3. The method of claim 1, wherein the polymerizable anionic monomer is selected from the group consisting of methylmethacrylate substituted with a negatively-charged group, methacrylate substituted with a negatively-charged group, acrylamide substituted with a negatively-charged group, and allyl substituted with a negatively-charged group.

4. The method of claim 3, wherein the negatively-charged group is sulfonate.

5. The method of claim 1, wherein the polymerizable anionic monomer is selected from the group consisting of 2-acrylamido-2-methyl-1-propane sulfonate and 2-(methacryloyloxy)ethane sulfonate.

6. The method of claim 1, wherein the polymerizable cationic monomer is selected from the group consisting of methylmethacrylate substituted with a positively-charged group, methacrylate substituted with a positively-charged group, acrylamide substituted with a positively-charged group, and allyl substituted with a positively-charged group.

7. The method of claim 6, wherein the positively-charged group is ammonium.

8. The method of claim 1, wherein the polymerizable cationic monomer is selected from the group consisting of [2-(methacryloyloxy)ethyl]trimethylammonium; [2-(methacryloyloxy)ethyl]trimethylammonium; and (4-vinylbenzyl)dimethylhexan-1-ammonium.

9. The method of claim 1, wherein the solvent is selected from the group consisting of chlorobenzene, toluene, chloroform, tetrahydrofuran, cyclohexanone, methanol, and mixtures thereof.

10. The method of claim 1, wherein making the film comprises making the film on a transparent conductive surface.

11. The method of claim 10, wherein the transparent conductive surface is selected from the group consisting of indium-tin-oxide and fluorine-doped tin-oxide.

12. The method of claim 1, wherein making the film comprises forming a metallic electrode on the film surface.

13. The method of claim 12, wherein the metallic electrode is selected from the group consisting of gold, silver, aluminum, copper, barium, calcium, and mixtures thereof.

14. The method of claim 1, wherein making the film comprises making the film on a transparent conducive surface and forming a metallic electrode on the film surface opposite the transparent conductive surface.

15. The method of claim 1, wherein the solution further comprises an ion-transport material.

16. The method of claim 15, wherein the ion-transport material comprises poly(ethylene oxide).

17. The method of claim 15, wherein the ion-transport material comprises a neutral thermoset monomer.

18. The method of claim 17, wherein the neutral thermoset monomer is selected from the group consisting of a polymerizable crown ether, methacrylate, methylmethacrylate, and styrene.

19. A film, comprising:
(a) a semiconducting polymer;
(b) an anionic polymer; and
(c) a cationic polymer.

20. The film of claim 19, comprising three regions:
(a) a first region, comprising the semiconducting polymer and the anionic polymer;
(b) a second region, comprising the semiconducting polymer and the cationic polymer; and
(c) a third region, intermediate the first and second regions, comprising the semiconducting polymer.

21. An electroluminescent device, comprising:
(a) a first electrode;
(b) a second electrode; and
(c) a polymer film intermediate the first and second electrodes, wherein the film comprises three regions:
(i) a first region comprising a semiconducting polymer and an anionic polymer;
(ii) a second region comprising the semiconducting polymer and a cationic polymer; and
(iii) a third region, intermediate the first and second regions, comprising the semiconducting polymer.

22. The device of claim 21, wherein the first or second electrode is a transparent conductor.

23. A photovoltaic device, comprising:
(a) a first electrode;
(b) a second electrode; and
(c) a polymer film intermediate the first and second electrodes, wherein the film comprises three regions:
(i) a first region comprising a semiconducting polymer and an anionic polymer;
(ii) a second region comprising the semiconducting polymer and a cationic polymer; and
(iii) a third region, intermediate the first and second regions, comprising the semiconducting polymer.

24. The device of claim 23, wherein the first or second electrode is a transparent conductor.

25. A method for producing light, comprising applying a voltage in forward bias to the electrodes of an electroluminescent device, the device comprising:
(a) a first electrode;
(b) a second electrode; and
(c) a polymer film intermediate the first and second electrodes, wherein the film comprises three regions:
(i) a first region comprising a semiconducting polymer and an anionic polymer;
(ii) a second region comprising the semiconducting polymer and a cationic polymer; and
(iii) a third region, intermediate the first and second regions, comprising the semiconducting polymer.

26. A method for converting light into electricity, comprising exposing a photovoltaic device to electromagnetic radiation to produce electricity, the photovoltaic device comprising:
(a) a first electrode;
(b) a second electrode, wherein the first and second electrodes are in electrical contact with a device for receiving an electrical current from the photovoltaic device; and
(c) a polymer film intermediate the first and second electrodes, wherein the film comprises three regions:
(i) a first region comprising a semiconducting polymer and an anionic polymer;
(ii) a second region comprising the semiconducting polymer and a cationic polymer; and
(iii) a third region, intermediate the first and second regions, comprising the semiconducting polymer.
